(19) United States
(12) Patent Application Publication
(10) Pub. No.: US 2010/0178137 A1
(43) Pub. Date: Jul. 15, 2010

(54) SYSTEMS, APPARATUS AND METHODS FOR MOVING SUBSTRATES

(75) Inventors: Prudhvi R. Chintalapati, Milpitas, CA (US); Satish Sundar, Bangalore (IN); Boris Axelrod, San Jose, CA (US); Mario Dave Silvetti, Morgan Hill, CA (US); Tom K. Cho, Los Altos, CA (US); Jeffrey A. Brodine, Los Altos, CA (US); Jason K. Foster, San Jose, CA (US); Edward Ng, San Jose, CA (US)

Correspondence Address: DUGAN & DUGAN, PC, 245 Saw Mill River Road, Suite 309, Hawthorne, NY, 10532, US

(73) Assignee: Applied Materials, Inc., Santa Clara, CA (US)

(21) Appl. No.: 12/684,754

(22) Filed: Jan. 8, 2010

Related U.S. Application Data
(60) Provisional application No. 61/143,805, filed on Jan. 11, 2009.

(51) Int. Cl. H01L 21/673; H01L 21/677

(52) U.S. Cl. 414/222.01; 414/806

(57) ABSTRACT

Systems, methods and apparatus are provided for moving substrates in electronic device manufacturing. In some aspects, end effectors having a base portion and at least three pads are provided. Each of the pads has a contact surface, and at least one of the contact surfaces has a curved shape. A substrate supported by the end effector may be moved at a relatively high lateral g-force without significant slipping relative to the pads. Additional aspects are provided.

### RELATED APPLICATIONS

The present application claims priority to U.S. Provisional Patent Application No. 61/143,805, filed Jan. 11, 2009, and entitled “SYSTEMS, APPARATUS AND METHODS FOR MOVING SUBSTRATES (Attorney Docket No. 13252/L), which is hereby incorporated herein by reference in its entirety for all purposes.

### FIELD OF THE INVENTION

The present invention relates to electronic device manufacturing and, more specifically, to systems, apparatus and methods for moving substrates.

### BACKGROUND OF THE INVENTION

In electronic device manufacturing, substrates (e.g., silicon wafers, glass plates, etc.) may be moved about manufacturing facilities and within manufacturing equipment by mechanical devices, including robots. The mechanical devices may contact the substrates with end effectors. End effectors are an important component in a manufacturing process as the quality of any final product may be improved when the substrates are moved with care.

### SUMMARY OF THE INVENTION

In a first aspect, a system for moving substrates in an electronic device manufacturing process is provided. The system includes a robot for moving substrates wherein the robot includes an end effector. The end effector includes a base portion and at least three pads disposed thereon wherein each of the pads includes a contact surface and at least one contact surface has a curved shape and a roughness of about 45 Ra to about 65 Ra.

In another aspect, an end effector for moving substrates is provided. The end effector includes a base portion and three pads disposed on the base portion wherein each of the pads has a contact surface and at least one of the contact surfaces has a curved shape.

In another aspect, an end effector for moving substrates is provided. The end effector includes a base portion including Ti-doped alumina ceramic, three pads including Ti-doped alumina ceramic disposed on the base portion, and a contact surface on each of the three pads wherein each of the contact surfaces has a curved shape with a radius of curvature of about 0.64 mm to about 9.53 mm and a roughness of about 45 Ra to about 65 Ra.

In another aspect, an end effector for moving substrates is provided. The end effector includes a base portion and at least three pads disposed on the base portion wherein each of the pads has a contact surface and at least one of the contact surfaces has a curved shape and a roughness of about 45 Ra to about 65 Ra.

In method aspect, a method for moving a substrate in an electronic device manufacturing process is provided. The method includes providing a substrate carrying robot, the robot including a robot arm, providing an end effector on the robot arm, the end effector including a base portion and at least three pads disposed thereon wherein each of the pads includes a contact surface and at least one of the contact surfaces has a curved shape and a roughness of about 45 Ra to about 65 Ra, placing the substrate in contact with the end effector, and moving the robot arm.

Other features and aspects of the present invention will become more fully apparent from the following detailed description, the appended claims and the accompanying drawings.

### BRIEF DESCRIPTION OF THE DRAWINGS

FIG. 1 is a schematic top plan view of an exemplary electronic device manufacturing processing tool provided in accordance with embodiments of the present invention.

FIG. 2 is a perspective view of an exemplary end effector provided in accordance with embodiments of the present invention.

FIG. 2a is a side view of an exemplary end effector of FIG. 2 provided in accordance with embodiments of the present invention.

FIG. 3 is a perspective view of another exemplary end effector provided in accordance with embodiments of the present invention.

FIG. 3a is a side view of an exemplary end effector of FIG. 3 provided in accordance with embodiments of the present invention.

FIG. 4 is an enlarged partial cross-sectional side view of an end effector having an exemplary pad disposed on a base portion provided in accordance with embodiments of the present invention.

FIG. 5 is an enlarged partial cross-sectional side view of another end effector having an exemplary pad disposed on a base portion provided in accordance with embodiments of the present invention.

FIG. 6 is a side view of a substrate contacting exemplary pads provided in accordance with embodiments of the present invention.

FIG. 6a is a side view of a bowed substrate contacting exemplary pads provided in accordance with embodiments of the present invention.

FIG. 7 is a flowchart of an exemplary method for moving a substrate provided in accordance with embodiments of the present invention.

FIG. 8 is a graphical representation of the results of substrate (wafer) placement tests with a 400 μm bowed semiconductor wafer.

FIG. 9 is a graphical representation of the results of substrate (wafer) placement tests with a 150 μm bowed semiconductor wafer.

FIG. 10 is a graphical representation of the results of substrate (wafer) placement tests with an inverted semiconductor wafer.

FIG. 11 is a graphical representation of the results of substrate (wafer) placement tests with a semiconductor wafer which was moved after silicon dust was placed on pads supporting the wafer.

### DETAILED DESCRIPTION

In electronic device manufacturing, substrates (e.g., silicon wafers, glass plates, etc.) are moved, often via a robotic device, through a number of manufacturing steps. Moving substrates quickly can increase throughput and, consequently, may reduce manufacturing costs. However, the substrates, even before they are completed, may have considerable value. Thus, care must be taken to avoid dropping or otherwise damaging the substrates as the substrates travel through the manufacturing steps. Also, particles on the substrates may complicate manufacturing. Generation of particles may increase when, among other things, substrates slide on a surface. Thus, it is preferable to minimize substrate sliding.

Embodiments of the present invention include an end effector with relatively non-slip characteristics. The end effector may include a base portion with at least three pads disposed thereon. Each pad may have a contact surface on which a substrate may be placed and at least one contact surface may be curved. A substrate may be placed in contact with the pads and may be moved by the end effector to and from the various manufacturing steps or locations, for example. In some embodiments, one or more of the pads may have a contact surface with a particular surface roughness which may further reduce a likelihood of substrate sliding. Additionally, the pads may be arranged on the base portion in a configuration that may contribute to the non-slip characteristics of the end effector. Thus, advantageously, substrates may be moved relatively quickly with reduced likelihood of falling off the end effector, minimized sliding leading to more repeatable and accurate substrate placement, and/or minimized generation of particles. In one aspect, the end effector may accommodate a variety of substrates, including those that may be imperfectly shaped, e.g., bowed.

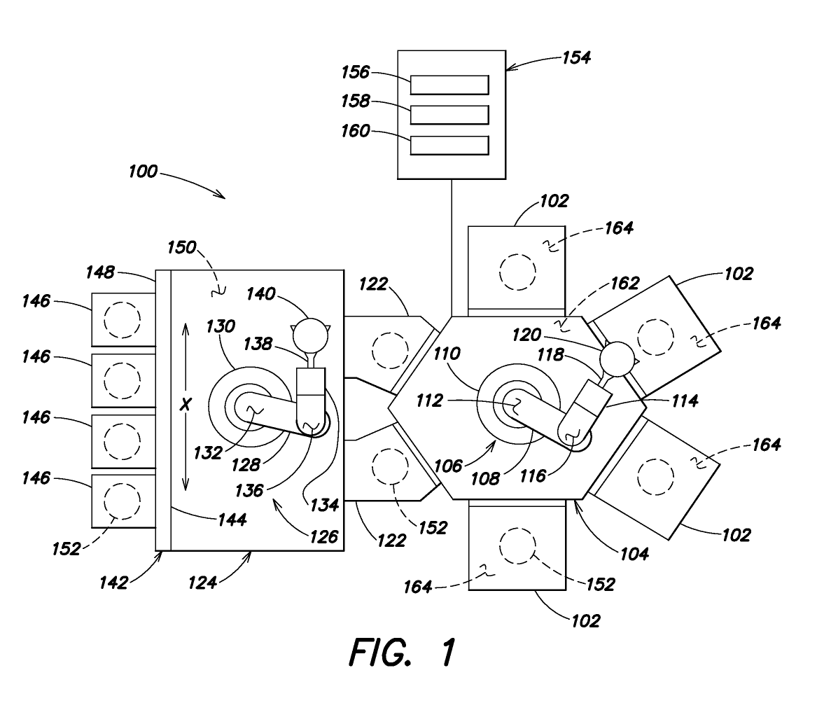

These and other embodiments of the systems, apparatus and methods are described below with reference to FIGS. 1-11.

FIG. 1 illustrates an exemplary electronic device processing tool 100 provided in accordance with an embodiment of the invention. Referring to FIG. 1, the processing tool 100 may include a number of processing chambers 102 coupled to a transfer chamber 104. The transfer chamber 104 may house a transfer chamber (TC) robot 106. The TC robot 106 may have a first arm 108 connected to a robot base 110 at a first linkage 112 and connected to a second arm 114 at a second linkage 116. An end effector 118 (partially hidden from view) may be attached to the second arm 114 distal the second linkage 116. The end effector 118 may contact (e.g., carry) a substrate 120 (e.g., a semiconductor wafer, glass plate, etc.).

The transfer chamber 104 of the processing tool 100 may be connected, via load lock chambers 122, to a factory interface 124. The factory interface 124 may house a factory interface (FI) robot 126. The FI robot 126 may have a first arm 128 connected to a robot base 130 at a first linkage 132 and connected to a second arm 134 at a second linkage 136. An end effector 138 (partially hidden from view) may be attached to the second arm 134 distal the second linkage 136. The end effector 138 may contact (e.g., carry) a substrate 140.

The FI robot 126 may sit on a track (not shown) which allows the FI robot 126 to move in a path parallel to a clean room wall 142, back and forth along the X direction. The factory interface 124 may be adjacent a first side of the clean room wall 144.

Substrate carriers 146 may be detachable and removably connected to a second side of the clean room wall 148 and may connect with an interior space of the factory interface 150 through openings in the clean room wall (not shown). Possible substrate locations 152 are shown by broken lines in the processing chambers 102, the load lock chambers 122 and the substrate carriers 146.

The processing tool 100 may be coupled to a controller 154. The controller 154 may control substrate movement and processing. The controller 154 may include a central processing unit (CPU) 156, support circuits 158 and a memory 160, for example. The CPU 156 may be one of any form of computer processor that can be used in an industrial setting for controlling various chambers and subprocessors. The memory 160 may be coupled to the CPU 156. The memory 160, may be a computer-readable medium, and may be one or more of readily available memory such as random access memory (RAM), read only memory (ROM), floppy disk, hard disk, or any other form of digital storage, local or remote. The support circuits 158 may be coupled to the CPU 156 for supporting the CPU 156 in any conventional manner. The support circuits 158 may include cache, power supplies, clock circuits, input/output circuitry, subsystems, and the like.

Processing tools may be arranged in a variety of configurations and a variety of robots may be used in different configurations, e.g., SCARA robots, 4-link robots, etc. Each robot will have at least one, but may have two or more, end effectors (sometimes referred to as blades) for contacting the substrates. End effectors may be, for example, gravity end effectors, vacuum end effectors and/or electrostatic end effectors. A transfer chamber interior space 162 and/or a processing chamber interior space 164 may be kept at a very low pressure or vacuum. Vacuum end effectors may not always be suitable in these environments as it may be difficult or impossible to generate a pressure differential to adhere a substrate to an end effector. Thus, for example, gravity end effectors may be particularly suitable, at least, in low pressure or vacuum environments.

In operation, the TC robot 106 may be arranged such that rotation at the first linkage 112 and second linkage 116 may, in combination, position and extend the second arm 114 and the end effector 118 to a desired location. The TC robot 106 may move substrates between the processing chambers 102 and the load lock chambers 122 or between different processing chambers 102, for example. In similar fashion, the FI robot 126 may also be arranged such that rotation at the first linkage 132 and the second linkage 136 will, in combination, position and extend the second arm 134 and the end effector 138 to a desired location. The FI robot 126 may move substrates between the load lock chambers 122 and the substrate carriers 146, for example. To do so, the FI robot may travel along the track (not shown), back and forth, in the X direction so that the FI robot 126 may access a number of substrate carriers 146.

As manufacturing processes progress, the FI robot 126 and the TC robot 106, working in tandem, may move substrates between the substrate carriers 146 and the processing chambers 102. Various electronic device fabrication processes, e.g., semiconductor device manufacturing processes, such as, e.g., oxidation, thin film deposition, etching, heat treatment, degassing, cool down, etc., may take place within the processing chambers 102.

It may be desirable for substrates to be moved as quickly as possible to speed up the manufacturing process and, consequently, to reduce manufacturing costs. However, as substrates are moved by the FI robot 126 and/or the TC robot 106 (or by other robots not discussed here or shown in FIG. 1) the likelihood of substrates sliding on one or more of the end effectors 118, 138 increases as the g-forces from the relatively rapid acceleration and deceleration of the end effectors increases. Sliding may occur, particularly, with gravity end effectors. Sliding may cause substrates to fall off end effectors consequently requiring the system operation to be delayed while the substrate is recovered. Falling substrates may slow the manufacturing process and may additionally result in damaged substrates. Thus, it may be desirable to use end effectors that reduce the likelihood of substrate sliding, at least, to prevent the substrates from falling off of the end effectors.

Also, sliding on the end effector may negatively affect the manufacturing process even when substrates do not fall off the end effectors. For example, a side of a substrate facing an end effector (i.e., a “backside” of a substrate) may accumulate particles (i.e., “backside particles”) when, among other things, a substrate slides on an end effector (“Particles” may also be referred to as “adders”). For example, sliding may scratch the surface of the substrate, forming the particles, and the particles may adhere to the backside of the substrate. These particles may find their way to the side of the substrate. In addition, it is undesirable to allow the substrate to be scratched, as scratching, alone, may reduce the quality of any final product. Moreover, particle generation may be generally detrimental as other substrates may be contaminated thereby. Furthermore, sliding may result in improper positioning of the substrates in process chambers, thereby possibly causing improper processing.

Since backside particles and/or substrate scratching may be reduced or eliminated by reducing or eliminating substrate sliding, end effectors that help to reduce or eliminate sliding may be highly beneficial in electronic device manufacturing. More specifically, it may be beneficial to reduce or eliminate substrate sliding so that substrates may experience relatively high g-forces without accumulating backside particles and/or without becoming scratched or otherwise damaged. Allowing substrates to experience relatively high g-forces allows manufacturing steps to proceed with reduced between process cycle time, and, thus, increased overall system throughput.

It may also be important that end effectors accommodate substrates of various shapes. For example, while most substrates are flat, or essentially flat, in some cases substrates may be bowed (e.g., concave or convex). Substrate shape may affect how and where substrates contact end effectors and, consequently, may affect the likelihood of substrate sliding. Further, substrates may slide differently due to, at least, substrate composition, etc. Also, in a manufacturing environment, various particles may be deposited on end effectors, e.g., silicone dust. These particles may increase the likelihood of substrate sliding.

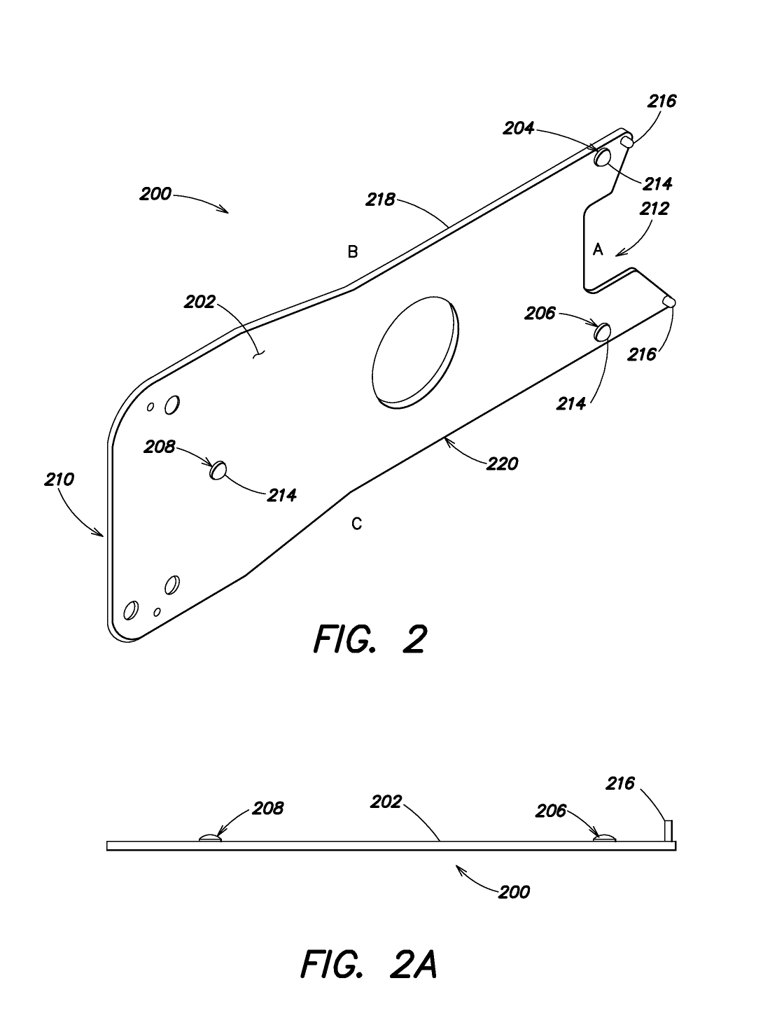

FIG. 2 depicts an exemplary embodiment of an end effector 200. The end effector 200 may comprise a base portion 202 with a first pad 204, a second pad 206 and a third pad 208 disposed thereon. The base portion 202 may include a base portion proximal end 210 and a base portion distal end 212. The proximal end 210 may be nearest to or attached to a robot arm (not shown) when the end effector 200 is in use. The end effector 200 may be configured such that it may be affixed to a robot arm by, e.g., screws, bolts, clamps, or the like. Each pad 204, 206, 208 may have a contact surface 214 which may be adapted to contact a substrate (not shown) when the substrate is placed in contact with the end effector 200. One or more of the first pad 204, second pad 206 and third pad 208 may have a contact surface 214 with a curved shape, for example. The base portion 202 also may have guard rails 216 disposed thereon to further assure that the substrate cannot slide off of the end effector 200.

The base portion 202 may be shaped such that substrates contacting the pads 204, 206, 208 may be lifted off of the end effector 200 by pins (not shown). The pins may, for example, rise up relative to the end effector 200, or the end effector 200 may be lowered while the pins remain stationery, or both the pins and end effector 200 may move simultaneously. A, B and C indicate locations where pins may, e.g., be located as a substrate is, e.g., placed in position on the pins. The base portion distal end 212 may be shaped such that a pin may, e.g., rise up relative to the end effector 200 at, e.g., location A. For example, the distal end 212 may be notched as shown.

The first pad 204 and the second pad 206 may be spaced relatively far apart from one another (to the extent permissible considering the dimensions of the base portion 202). The first pad 204 may be positioned relatively close to a base portion first edge 218 as well as relatively close to the base portion distal end 212. The second pad 206 may be positioned relatively close to a base portion second edge 220 as well as relatively close to the base portion distal end 212. As compared to the first pad 204 and the second pad 206, the third pad 208 may be positioned relatively closer to the base portion proximal end 210 and may be located approximately at a midpoint between the base portion first edge 218 and the base portion second edge 220.

FIG. 2a shows the side view of the end effector 200 shown in FIG. 2, but without guard rails. The pads 206, 208 and 204 (not shown in FIG. 2a) may be disposed on the base portion 202 such that the pads contact substrates placed in contact with the end effector.

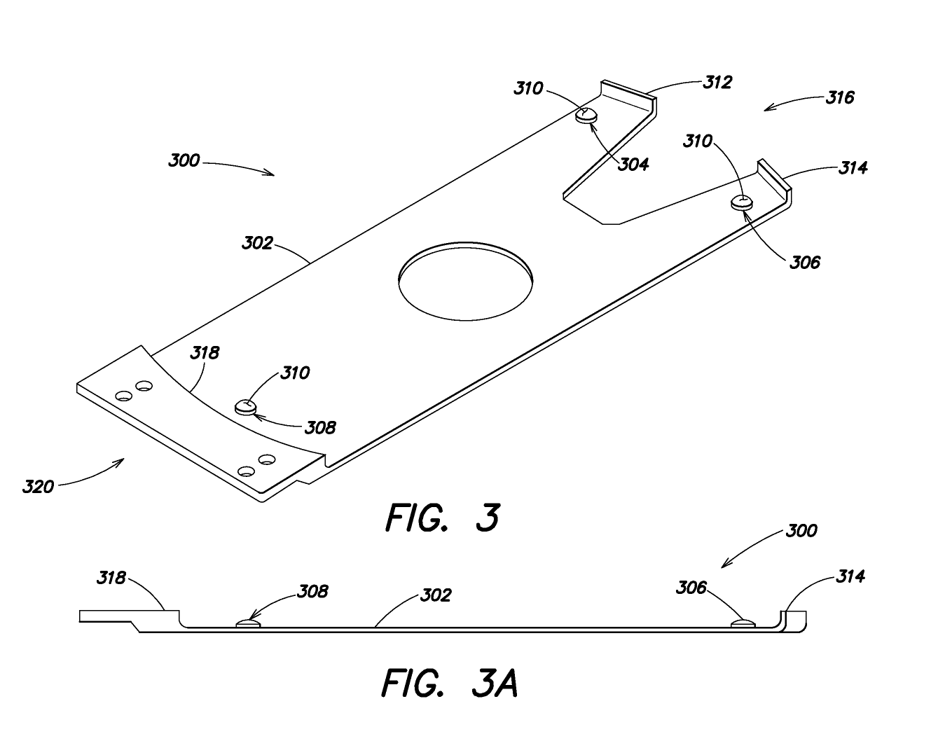

FIG. 3 depicts another exemplary embodiment of an end effector 300. As with the end effector shown in FIG. 2, the end effector 300 shown in FIG. 3 may comprise a base portion 302 and a first pad 304, a second pad 306 and a third pad 308 disposed thereon. Each pad may have a contact surface 310. The pads 304, 306, 308 may be positioned in a manner which may be similar to the embodiment shown in FIG. 2. A first guard rail 312 and a second guard rail 314, are both positioned at a base portion distal end 316, and may be relatively larger than the guard rails shown in the embodiment shown in FIG. 2. The guard rails 312, 314 may be comprised of a raised area of the base portion 302. A third guard rail 318, which also may be comprised of a raised area of the base portion 302, may be positioned closer to a base portion proximal end 320 than the third pad 308. One or more of the guard rails 312, 314, 318 may be rounded on a horizontal plane of the end effector 300 such that they approximate a rounded shape of a circumference of a substrate.

FIG. 3a shows the side view of the end effector 300 shown in FIG. 3. This view shows the second guard rail 314 and third guard rail 318 as raised portions of the base portion 302. The pads 306, 308 and 304 (not shown in FIG. 3a) may be disposed on the base portion 302 such that the pads contact substrates placed in contact with the end effector.

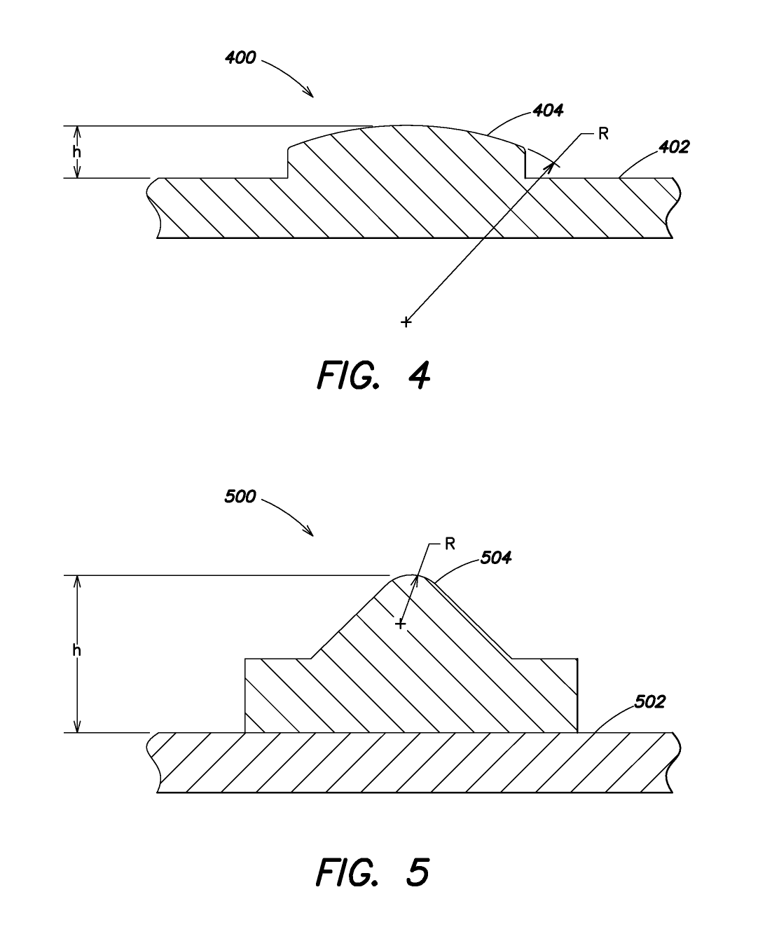

FIG. 4 shows an enlarged partial cross-sectional side view of an end effector having an exemplary pad 400 disposed on a base portion 402. The pad 400 has a contact surface 404 which may contact a substrate (not shown). The contact surface 404 may be curved. The contact surface 404 of this embodiment may have a radius of curvature (R) of about 0.375 inches (9.53 mm). The roughness of the contact surface 404 may be between about 45 Ra to about 65 Ra specified based on the ASME Y14.36M-1996 standard. The height (h) of the pad 400, measured from the base portion 402 to the highest point on the pad contact surface 404 may be about 0.075 inches (1.9 mm), for example. The pad 400 may have sufficient height (h) such that, in addition to flat substrates, bowed substrates may contact a number of pads without contacting the base portion 402. As discussed below, the curved contact surface 404 may ensure that a substrate, whether flat or bowed, may make a stable contact with the contact surface 404. The diameter of the pad may be about 0.313 inches (7.95 mm). In the embodiment shown in FIG. 4, the pad 400 and the base portion 402 are one solid piece of material, i.e., both the pad 400 and the base portion 402 are machined from the same piece of material.

FIG. 5 shows an enlarged partial cross-sectional side view of another end effector having an exemplary pad 500 disposed on a base portion 502. The pad 500 has a contact surface 504 which may contact a substrate (not shown). The contact surface 504 may be curved, and may have a radius of curvature (R) of 0.025 inches (0.64 mm). The roughness of the contact surface 504 may be about 45 Ra to about 65 Ra. The height (h) of the pad 500, measured from the base portion 502 to the highest point on the pad contact surface 504 may be about 0.075 inches (1.9 mm), for example. The pad 500 may have sufficient height such that, in addition to flat substrates, bowed substrates may contact a number of pads without contacting the base portion 502. As discussed below, the curved contact surface 504 may ensure that a substrate, whether flat or bowed, may make a stable contact with the contact surface 504. The diameter of the pad may be about 0.313 inches (7.95 mm). In the embodiment shown in FIG. 5, the pad 500 and the base portion 502 are manufactured separately and, thereafter, the pad 500 is affixed to the base portion 502 with, e.g., an adhesive such as an epoxy and/or with a bolt or screw.

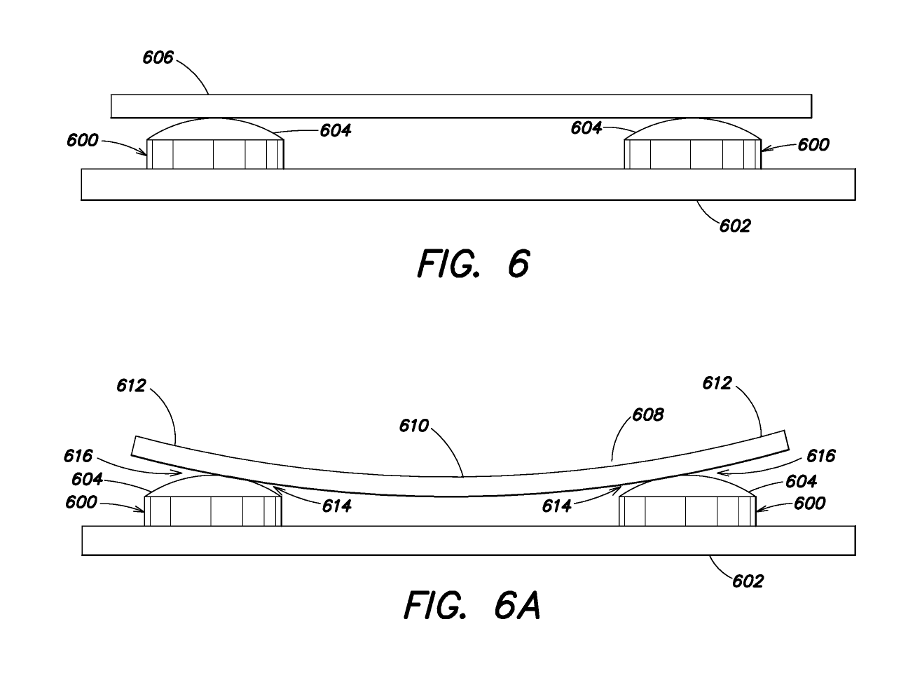

FIG. 6 shows two exemplary pads 600 disposed on a base portion 602. Each pad 600 has a contact surface 604 which contacts an essentially flat substrate 606. FIG. 6a shows a bowed substrate 608 contacting the contact surfaces 604 of the same exemplary pads 600 shown in FIG. 6. FIG. 6a shows how the curved contact surfaces 604 will make relatively good contact even with the bowed substrate 608.

In FIG. 6a, the bowed substrate central portion 610 is relatively closer to the base portion 602 as compared to the bowed substrate outer portion 612. Thus, the bowed substrate 608 contacts the contact surfaces inner portions 614. If, e.g., (not shown) a bowed substrate central portion 610 was relatively further from the base portion 602 as compared to the bowed substrate outer portion 612, the bowed substrate 608 would contact the contact surfaces outer portions 616.

In some embodiments, the end effector may be comprised of a base portion and least three pads disposed thereon. Each of the pads may have a contact surface and at least one of the contact surfaces on at least one of the pads may have a curved shape. Pads with a curved shape may have a convex profile when viewed from at least one side angle (See, e.g., FIGS. 4 and 5). In some embodiments, the contact surface may have a convex curved shape which is symmetrical when viewed from one or more or even all side angles. For example, a contact surface may have a symmetrical curved shape which gives the contact surface a symmetrical convex appearance, i.e., such as that of a dome, when viewed from any side. However, contact surfaces may be unsymmetrical. Any contact surface may be curved with a different radius of curvature at different points of the contact surface, i.e., contact surfaces may be curved at one or more locations or may be evenly or unevenly curved over their surface. At least one pad may have a curved surface that contacts substrates when substrates are placed in contact with the end effector. Pads and/or pad contact surfaces may have, e.g., a generally cylindrical, cubical, conical or other shape. Each pad may be differently shaped or each pad may be shaped similarly to the other pads.

The end effector may have only three pads, more than three pads (e.g., four pads), or more than four pads disposed on the base portion. In embodiments with three pads, the pads may, but need not, be arranged as shown in FIGS. 2 and 3. In embodiments with four or more pads, two pads may be arranged relatively far apart from one another on the proximal end of the base portion in a similar fashion to the pads shown on the base portion distal end 212 (Referring to FIG. 2).

The base portion and/or one or more pads and/or one or more guard rails may, for example, be comprised of a material with relatively low heat conductivity, relatively high stiffness to weight ratio and a relatively low thermal expansion coefficient. The base portion and/or one or more pads and/or one or more guard rails may, for example, be comprised of a material with a density of about 3.96 g/cc, and/or a modulus of elasticity of about 370 GPa, and/or a coefficient of thermal expansion of about 7.4 μm/m-° C., and/or an operating temperature limit of about 2000° C.

End effectors may, for example, have a weight of about 0.44 (0.2 kg) to about 0.53 lbs (0.24 kg), and/or a droop (deflection at a terminal end of the end effector under its own weight) of about 0.013 (0.33 mm) to about 0.015 inches (0.38 mm) and/or a first natural frequency of about 47.9 Hz to about 49.3 Hz.

The base portion and/or one or more pads and/or one or more guard rails may be formed of an electrically conductive material so as to prevent arcing and to provide a ground path for electrical discharge. For example, the base portion and/or one or more pads and/or one or more guard rails may be comprised of, e.g., stainless steel, alumina, nickel-plated aluminum, or the like. The base portion and/or one or more pads and/or one or more guard rails may be formed of ceramic, for example, zirconia, silicon carbide, or Ti-doped ceramic. The base portion and/or one or more pads and/or one or more guard rails may be formed of Ti-doped ceramic made of about 99.5% alumina. In some embodiments, the base portion and/or one or more pads and/or one or more guard rails may be formed of a material with a surface resistivity range of between about 1×10⁶ and about 1×10¹³ ohms/cm. The base portion and/or one or more pads and/or one or more guard rails may be made of the same material or of different materials.

In some embodiments, the base portion and/or one or more pads and/or one or more guard rails may be machined with the base portion from one piece, e.g., a single block, of material. Thus, for example, the base portion, all pads and all guard rails may all be machined as one solid piece of material. In other embodiments, one or more of the pads disposed on the base portion and/or one or more of the guard rails disposed on the base portion may be manufactured separately and affixed to the base portion with, e.g., an adhesive, such as an epoxy and/or one or more screws, press fit, or the like.

In some embodiments, pads may be spread relatively far from one another to provide distances between the pads sufficient for the substrate's surface area. Pads may be positioned, e.g., such that two or more pads are positioned towards the base portion distal end and one or more pads are positioned towards the base portion proximal end (See FIG. 2). Pads may be positioned, e.g., such that two or more pads are positioned towards the base portion proximal end and one or more pads are positioned towards the base portion distal end. The end effector may, but need not, include guard rails.

The base portion may be manufactured from more than one piece of material or may be one solid piece of material. In the event that the base portion is more than one piece, each piece of the base portion may contain no pads or one or more pads and each piece of the base portion may be manufactured from the same material or of different materials as the other piece(s) of the base portion and/or one or more pads and/or one or more guard rails.

Embodiments of the invention may find utility as gravity end effectors, vacuum end effectors and/or electrical end effectors such as electrostatic end effectors.

In some embodiments of the invention, pads may have a contact surface radius of curvature (R) (See FIGS. 4 and 5) in the range of, e.g., about 0.025 inches (0.64 mm) to about 0.375 inches (9.53 mm). Substrates may contact one or more pads at different locations on the pad contact surfaces, depending, at least, on the substrate shape and the contact surface shape.

In embodiments of the invention, one or more pad contact surfaces may have a surface roughness of about 45 Ra to about 65 Ra. One or more pads may, e.g., have a height (h) (See, e.g., FIGS. 4 and 5) of about 0.050 inches (1.3 mm) to about 0.1 inches (3 mm). One or more pads may have a height of about 0.075 inches (1.9 mm). The height (h) of each pad may be, but may not be, identical to the height (h) of the other pads disposed on a base portion. In some embodiments, the height of each pad may be sufficient to prevent a bowed pad from contacting the base portion of the end effector. Any pad, including the pad contact surface, may, e.g., be comprised of one homogenous, or essentially homogenous, material. One or more pads may have a diameter of between about 0.2 to about 0.5 inches, and in some embodiments about 0.313 inches.

Substrates may rest on or may be placed on (i.e., placed on a top side of) end effectors and may remain in place by the force of gravity. However, embodiments of the invention may include electrostatic, vacuum or other types of end effectors which may contact and adhere to substrates in ways, in addition to, or other than, gravity. Thus, embodiments of the invention may have application to situations in which an end effector contacts a top side of a substrate rather than a bottom or backside of a substrate. For example, a substrate may be positioned below an end effector with which it is in contact.

In operation, a substrate may be placed in contact with an end effector such that the substrate makes contact with pad contact surfaces. In some circumstances, a bowed substrate may be placed in contact with the end effector such that the substrate contacts the pad contact surfaces. The end effector may accelerate and/or decelerate with a relatively high g-force, and the substrates will not slide or, alternatively, will slide only a relatively insignificant distance. Thus, any damage to substrates from sliding, which may cause scratching or which may result in substrates falling off of the end effector, is significantly reduced. Since sliding may be reduced, the generation and accumulation of particles from the pad and/or substrates may also be reduced.

In some embodiments, the end effector may maintain substrate placement within about ±0.005 inches (0.13 mm), or within about ±0.0044 inches (0.11 mm), or even within about ±0.00335 inches (0.085 mm), while moving with an acceleration of at least 0.13 g. In further embodiments, the end effector may maintain substrate placement within about ±0.0029 inches (0.074 mm) or even about ±0.0009 inches (0.02 mm) while moving with an acceleration of at least 0.13 g.

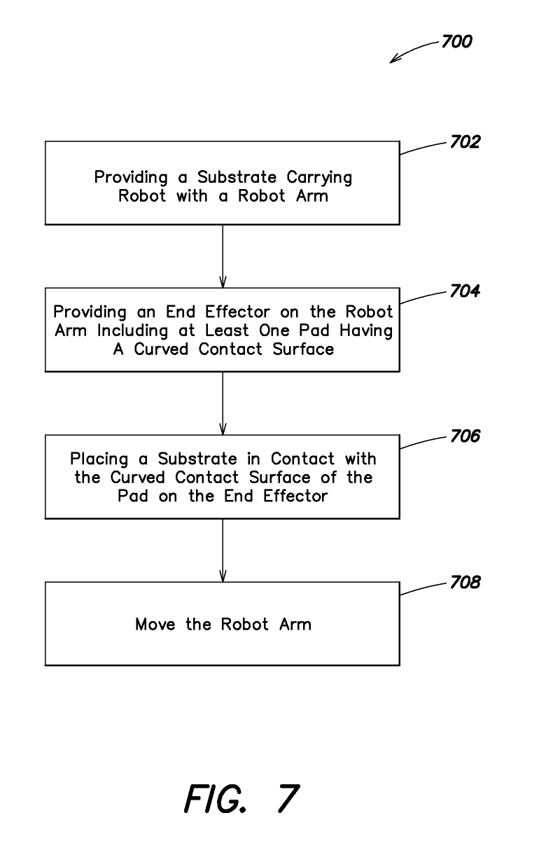

FIG. 7 is an exemplary flowchart of a manufacturing method utilizing a robot equipped with an end effector of the invention to move a substrate. According to the method 700, in step 702, a robot configured with an arm suitable for carrying substrates is provided. In step 704, an end effector of the invention having at least one pad including a contact surface having a curved shape is provided on the robot arm through suitable attachment thereto. The pad may further include a surface roughness as described above. In step 706, a substrate is placed in contact with the pads of the end effector. In step 708, the robot arm is moved, such that the end effector and the substrate contacting the end effector are moved. The process described above may be repeated any number of times with a variety of end effectors and substrates.

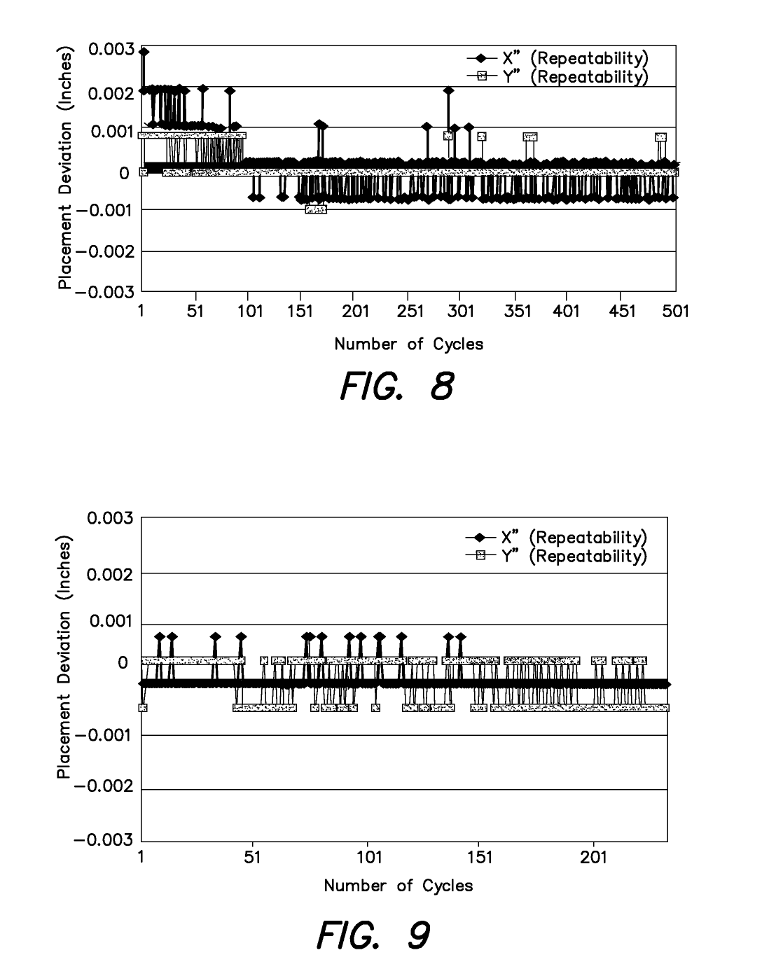

FIGS. 8-11 illustrate various plots of data showing the placement deviations from the intended placement position when moving the substrate at 0.13 G with the end effector of the present invention. All tests were run with Ti-doped, 99.5% Alumina Ceramic end effectors with domed pads comprised of the identical ceramic material.

The substrate tested in FIG. 8 is a highly bowed wafer having a compressive bow of about 400 microns. FIG. 8 illustrates a maximum placement deviation (in inches) of +/−2.9 mils at 0.13 g lateral acceleration over roughly 500 cycles. Accordingly, this plot illustrates that the present invention including domed pads is highly effective at controlling placement deviations on bowed substrates at relatively high g conditions.

FIG. 9 illustrates a substrate carried by the end effector which is a less bowed silicon wafer having a tensile bow of about 150 microns. FIG. 9 illustrates a maximum placement deviation (in inches) of +/−2.9 mils at 0.13 g lateral acceleration over roughly 250 cycles. This plot illustrates that the present invention including domed pads is highly effective at controlling placement deviations on even tensile bowed wafers at relatively high g conditions.

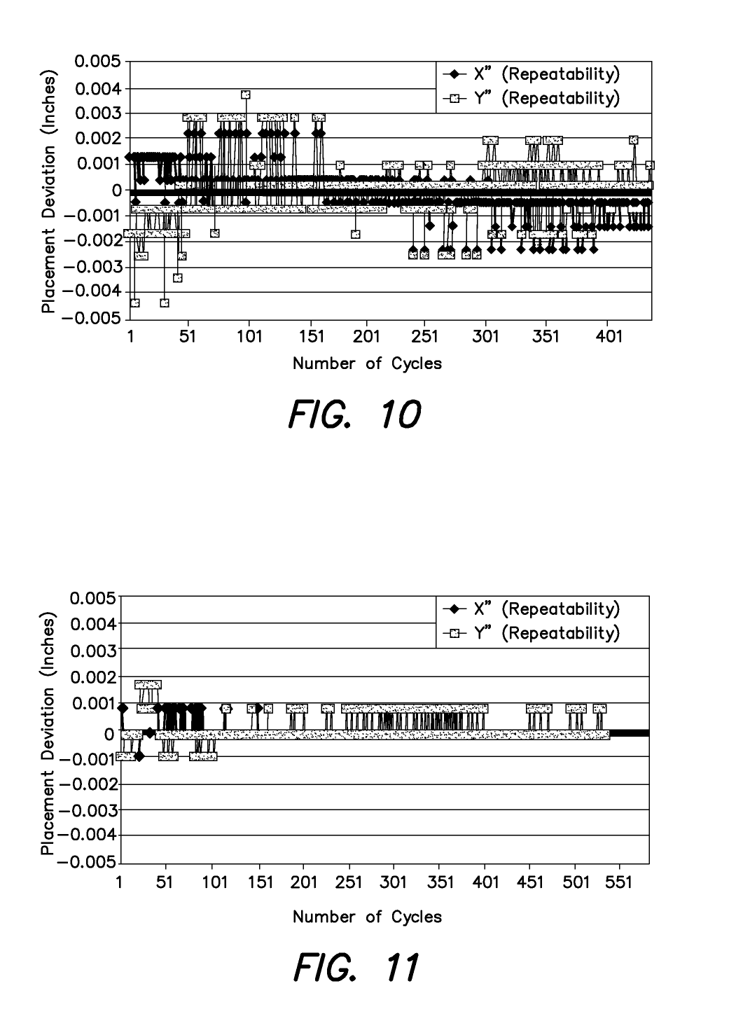

FIG. 10 illustrates test data for a substrate which is a bowed silicon wafer having a low friction surface condition (μ=0.11 to 0.13). FIG. 10 illustrates a maximum placement deviation (in inches) of +/−4.4 mils at 0.13 g lateral acceleration over roughly 450 cycles. This plot illustrates that the present invention including domed pads is highly effective at controlling placement deviations at relatively high g conditions even on low friction wafers.

FIG. 11 illustrates test data for a substrate which is a silicon wafer where the pads have been liberally sprinkled with silicon dust to mock a possible in-use condition. FIG. 11 illustrates a maximum placement deviation (in inches) of +/−3.35 mils at 0.13 g lateral acceleration over roughly 550 cycles. This plot illustrates that the present invention including domed pads is highly effective at controlling placement deviations at relatively high g conditions even when the pads are exposed to silicon dust.

The foregoing description discloses only exemplary embodiments of the invention. Modifications of the above-disclosed systems, apparatus and methods which fall within the scope of the invention will be readily apparent to those of ordinary skill in the art. For example, exact pad placement and the number of pads used may vary in different embodiments of the invention.

Accordingly, while the present invention has been disclosed in connection with exemplary embodiments thereof, it should be understood that other embodiments may fall within the spirit and scope of the invention, as defined by the following claims.

The invention claimed is:

1. A system for moving substrates in an electronic device manufacturing process, comprising:
a robot for moving substrates, the robot comprising an end effector, the end effector comprising
a base portion, and
at least three pads disposed on the base portion wherein each of the pads comprises a contact surface and at least one contact surface has a curved shape and a roughness of about 45 Ra to about 65 Ra.

2. The system of claim 1, consisting essentially of three pads.

3. The system of claim 1, comprising four pads.

4. The system of claim 1, comprising more than four pads.

5. The system of claim 1, wherein the at least one contact surface has a radius of curvature of about 0.64 mm to about 9.53 mm.

6. The system of claim 1, wherein the base portion and at least one of the pads are comprised of electrically conductive material.

7. An end effector for moving substrates, comprising:
a base portion; and
three pads disposed on the base portion wherein each of the pads has a contact surface and at least one of the contact surfaces has a curved shape.

8. The end effector of claim 7, wherein the contact surface having a curved shape has a radius of curvature of about 0.64 mm to about 9.53 mm.

9. The end effector of claim 7, wherein the contact surface having a curved shape has a surface roughness of about 45 Ra to about 65 Ra.

10. The end effector of claim 7, wherein the base portion is comprised of electrically conductive material.

11. The end effector of claim 7, wherein the base portion is comprised of conductive material chosen from the group consisting of stainless steel, alumina, nickel-plated aluminum, zirconia and silicon carbide.

12. The end effector of claim 7, wherein at least one pad is comprised of electrically conductive material.

13. The end effector of claim 7, wherein at least one pad is comprised of conductive material chosen from the group consisting of stainless steel, alumina, nickel-plated aluminum, zirconia and silicon carbide.

14. The end effector of claim 7, wherein the pads and the base portion are machined from a single piece of material.

15. An end effector for moving substrates, comprising:
a base portion comprised of Ti-doped alumina ceramic; and
three pads comprised of Ti-doped alumina ceramic disposed on the base portion wherein each of the three pads includes a contact surface having a curved shape with a radius of curvature of about 0.64 mm to about 9.53 mm and a roughness of about 45 Ra to about 65 Ra.

16. An end effector for moving substrates, comprising:
a base portion; and
at least three pads disposed on the base portion wherein each of the pads has a contact surface and at least one of the contact surfaces has a curved shape and a roughness of about 45 Ra to about 65 Ra.

7. The end effector of claim 16, wherein the contact surface having a curved shape has a radius of curvature of about 0.64 mm to about 9.53 mm.

18. The end effector of claim 16, wherein the base portion is comprised of electrically conductive material.

19. The end effector of claim 16, wherein at least one pad is comprised of electrically conductive material.

20. The end effector of claim 16, wherein the pads and the base portion are machined from a single piece of material.

21. A method for moving a substrate in an electronic device manufacturing process, comprising:
providing a substrate carrying robot, the robot comprising a robot arm;
providing an end effector on the robot arm, the end effector comprising a base portion and at least three pads disposed thereon wherein each of the pads comprises a contact surface and at least one of the contact surfaces has a curved shape and a roughness of about 45 Ra to about 65 Ra;
placing the substrate in contact with the end effector; and
moving the robot arm.

22. The method of claim 21, wherein the end effector will maintain substrate placement within ±0.13 mm while moving with an acceleration of at least 0.13 g.

23. The method of claim 22, wherein the end effector will maintain substrate placement within ±0.085 mm while moving with an acceleration of at least 0.13 g.

24. The method of claim 23, wherein the end effector will maintain substrate placement within ±0.02 mm while moving with an acceleration of at least 0.13 g.
